(19) United States
(12) Patent Application Publication
(10) Pub. No.: US 2024/0396568 A1
(43) Pub. Date: Nov. 28, 2024

(54) ADAPTIVE ANALOG PARTIAL SUM ACCUMULATION TECHNOLOGY FOR ENERGY-EFFICIENT COMPUTE-IN-MEMORY

(71) Applicant: Intel Corporation, Santa Clara, CA (US)

(72) Inventors: Renzhi Liu, Portland, OR (US); Hechen Wang, Portland, OR (US); Richard Dorrance, Hillsboro, OR (US); Brent Carlton, Portland, OR (US)

(21) Appl. No.: 18/792,714

(22) Filed: Aug. 2, 2024

(51) Int. Cl. H03M 1/14; G06F 7/544; H03M 1/18

(52) U.S. Cl. CPC H03M 1/144; G06F 7/5443; H03M 1/181

(57) ABSTRACT

Systems, apparatuses and methods may provide for technology including a digital to analog conversion (DAC) stage to generate analog input activation signals, a multiply-accumulate (MAC) computation stage coupled to the DAC stage, the MAC computation stage to generate output activation results based on the analog input activation signals and multi-bit weight data stored in the MAC computation stage, an analog integration stage coupled to the MAC computation stage, the analog integration stage to conduct partial sum accumulations on the output activation results, and analog to digital conversion (ADC) stage coupled to the analog integration stage, the ADC stage to generate digital computation results based on an output of the analog integration stage, and a controller to vary a number of cycles in the partial sum accumulations based on an overflow condition associated with one or more of the output activation results or the output of the analog integration stage.

### BACKGROUND OF THE DISCLOSURE

Compute-in-Memory (CiM) technology has recently become one of the leading hardware candidates for accelerating the execution and training of convolutional neural network (CNN) and deep neural network (DNN) applications. CiM does so by directly addressing a “memory wall” in which limited bandwidth between memory and compute hardware in modern architectures causes bottlenecks in the system, leading to poor computational and energy efficiency. The development of CiM solutions, however, is more difficult to realize as a pure digital system, because conventional multiply-accumulate (MAC) operation units of CiM are too large to fit within high-density memory arrays.

Although analog-based CiM methods may be used to increase the efficiency and throughput of in-memory MAC computations, there remains considerable room for improvement. For example, the energy efficiency of analog-based CiM solutions may be fundamentally limited by power consumption from analog to digital conversion (ADC) hardware that digitizes MAC partial sum results from the analog domain into digital bits for further accumulation in the digital domain.

### BRIEF DESCRIPTION OF THE DRAWINGS

The various advantages of the embodiments will become apparent to one skilled in the art by reading the following specification and appended claims, and by referencing the following drawings, in which:

FIG. 1 is a schematic diagram of an example of an analog compute-in-memory (CiM) circuit according to an embodiment;

FIG. 2 is a signaling diagram of an example of a set of signals issued in an analog CiM circuit according to an embodiment;

FIG. 3 is a schematic diagram of an example of a charge-domain analog CiM circuit according to an embodiment;

FIG. 4 is a flowchart of an example of a method of operating an analog CiM circuit according to an embodiment;

FIG. 5 is a block diagram of an example of a performance-enhanced computing system according to an embodiment; and

FIG. 6 is an illustration of an example of a semiconductor package apparatus according to an embodiment.

### DETAILED DESCRIPTION

As already noted, the energy efficiency of conventional analog-based compute-in-memory (CiM) solutions may be limited by power consumption from analog to digital conversion (ADC) hardware that digitizes the multiply-accumulate (MAC) partial sum (summation) results from the analog domain into digital bits for further accumulation in the digital domain. More particularly, regarding how many multiplication products should be included in one partial sum before digitization in analog CiM, there exists a fundamental tradeoff between MAC energy efficiency and the ADC digitization accuracy.

Specifically, on one side of the tradeoff, for reaching higher energy efficiency per MAC operation, it is advantageous to have more multiplication products summed and averaged in the analog domain in one partial sum for a single ADC digitization operation (e.g., therefore the ADC energy consumption can be amortized further for each MAC operation). On the other side of the tradeoff, more multiplication products within one partial sum results in a larger averaging factor for the analog output being used to prevent overflowing or saturating the analog values before digitization. A larger averaging factor (e.g., a larger division number), would further constrain the accuracy requirement for the ADC digitization process, requiring higher number of bits from one ADC conversion. The result would be a significantly increased ADC energy consumption. The technology described herein provides an analog partial sum accumulation scheme that further accumulates multiple partial sums in the analog domain adaptively without resulting in a larger averaging factor (e.g., breaking the tradeoff and significantly reducing ADC energy consumption per MAC operation).

Embodiments add an analog accumulation stage between analog output activation (OA) lines and the ADC input, while using an overflow detector at the ADC input to adaptively control whether the analog partial sum accumulation process continues. By doing so, another level of analog partial sum accumulation is added in the analog CiM circuit (e.g., macro) that is beyond the summation and averaging that already occurred on each OA line within one MAC computation cycle. This additional accumulation is conducted without increasing the averaging factor for summation of the multiplication products. Accordingly, the output values are not reduced and ADC digitization precision is not constrained. With the additional analog accumulation occurring for an increased number of multiplication products before conducting ADC digitization, the ADC energy consumption is further amortized for each MAC operation (e.g., achieving higher energy efficiency for CiM MAC operation). Introducing the overflow detector renders the analog partial sum accumulation scheme adaptive such that a risk of analog value saturation at the ADC input or partial sum result overflow in the digital domain is not encountered.

The technology described herein therefore provides performance advantages relative to conventional in-memory computing solutions in terms of higher throughput and higher efficiency, particularly in edge artificial intelligence (AI) platforms. Indeed, embodiments improve the energy-efficiency of analog CiM because ADC energy consumption is typically the dominant energy consumption source in analog CiM macros. For example, by improving ADC energy amortization per MAC operation, the overall MAC operation energy efficiency is significantly increased. Moreover, the adaptive nature of analog partial sum accumulation as described herein boosts the energy efficiency of the analog CiM macro while keeping the analog partial sum in range for digitization.

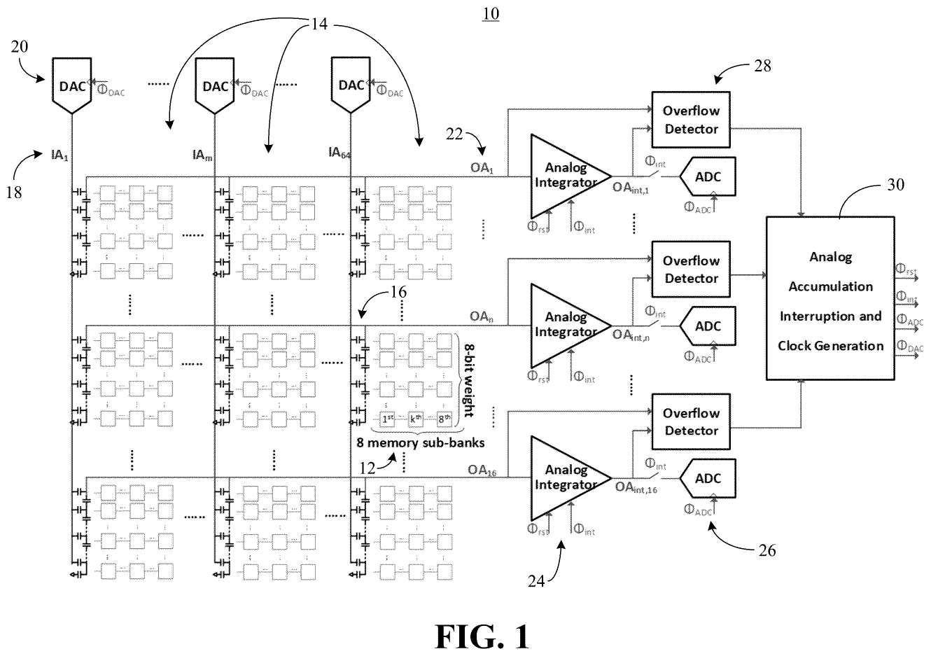

Turning now to FIG. 1, an enhanced analog CiM circuit 10 (e.g., macro) is shown. In the illustrated example, weight storage (e.g., static random access memory/SRAM) within a MAC computation stage 14 of the analog CiM circuit 10 includes multiple groups 12 of sub-banks, wherein each group 12 of sub-banks shares the same analog computation unit 16. For example, a localized data multiplexing capability from sub-banks of bits can be created through enhanced SRAM cell design. To facilitate discussion, the illustrated analog CiM circuit 10 includes sixty-four columns of input activation (IA) lines 18 from a digital to analog conversion (DAC) stage 20 including sixty-four DACs, and sixteen rows of output activation (OA) lines 22 to output analog partial sums. Each OA line 22 generates a partial sum from sixty-four multiplication products between sixty-four IA lines 18 in the analog domain and sixty-four weights in the digital domain (e.g., multi-bit weight data stored in the CiM MAC array). Each weight has an 8-bit integer (INT8) format, with there being the group 12 of eight memory sub-banks that share the analog computation unit 16 through localized SRAM bit multiplexing (not shown).

In general, a partial sum/summation is a portion of a full summation. For example, if a full summation operation involves 1024 numbers summed together, then a “partial sum” refers to any subset of the 1024 numbers summed together (e.g., 64 numbers out of 1024 numbers summed together making up one “partial sum”). In the context of MAC operation for AI and/or machine learning (ML) applications, “partial sum” is then the summation of a portion of the multiplication products that would have been included in one complete MAC operation (e.g., the MAC operation that produces one final output number before activation function). For example, if a complete MAC operation involves summation of 1024 multiplication products, then a partial sum as described herein can be the summation of 64 multiplication products (or any other numbers that are smaller than 1024) out of those 1024 multiplication products.

Although the illustrated analog computation unit 16 is a C-2C ladder-based MAC unit, other analog computation solutions may also be used. Assuming W_{n,m,k} is the decimal representation of the 8-bit weight that is stored in the n^{th} row, m^{th} column, and k^{th} sub-banks of the CiM MAC array, then the value on the n^{th} OA line 22 after each MAC operation, which is the partial sum of sixty-four multiplication products is:

$${OA}_{n} = \frac{1}{64} {\sum }_{m = 1}^{64} ( \frac{1}{256} \cdot {W}_{n , m , k} \cdot {IA}_{m} ) \qquad Eq . 1$$

The 1/256 scaling factor normalizes the 8-bit data to the range of [0,1]. Meanwhile, the 1/64 scaling factor demonstrates that the nature of the analog MAC operation is not truly summation but rather averaging for the sixty-four multiplication products. Therefore, with a larger number of multiplication products included within one partial sum, the weighting for each individual multiplication product of W_{n,m,k}·IAₘ is reduced (e.g., resulting in a higher ADC resolution being used if the same level of digitization accuracy is to be maintained for each W_{n,m,k}·IAₘ operation).

The technology described herein adds at least three enhancements to conventional analog CiM operation:

(1) An analog integration stage 24 is added between the OA lines 22 of partial sum output and an input to an ADC stage 26. Thus, in the k^{th} cycle of MAC operation, weights from the kl sub-bank are used for computation and the inputs are IAₘ(k) and outputs are OAₙ(k), respectively. After analog accumulation in eight cycles, the n^{th} OA output after integration, OA_{int,n}, is:

$${OA}_{int , n} = {A}_{int} {\sum }_{k = 1}^{8} {OA}_{n} ( k ) = \frac{{A}_{int}}{64} {\sum }_{k = 1}^{8} {\sum }_{m = 1}^{64} ( \frac{1}{256} \cdot {W}_{n , m , k} \cdot {IA}_{m} ( k ) ) \qquad Eq . 2$$

Here Aᵢₙₜ is the gain of the analog integrator for each MAC cycle. This gain can be set to the value of one for not providing additional gain or set to a value greater than one to provide some gain before ADC digitization. Additionally, every accumulation cycle may involve a different sub-bank of weights. Therefore, since there are only eight sub-banks in this example, the analog partial sum accumulation is only operated for at most eight cycles. Eq. 2 also demonstrates that the analog integration stage 24 performs integration or summation operations, without adding another dividing factor to the OA output (e.g., which would further reduce the weighting of each multiplication product in the analog domain). This approach is in direct contrast to simply adding more multiplication products within one partial sum through the addition of more columns and DACs in the array. By way of comparison, Eq. 2 involves eight cycles of 64-dimensional MAC partial sum outputs, which is a total of 512 multiplication products, added together into one integrated OA output. If 512 multiplication products were to be connected into one OA line 22 by having 512 columns and 512 DACs, the result would be:

$${OA}_{n} = \frac{1}{512} {\sum }_{m = 1}^{512} ( \frac{1}{256} \cdot {W}_{n , m , k} \cdot {IA}_{m} ) \qquad Eq . 3$$

Comparing Eq. 3 with Eq. 2, while assuming the analog integration stage 24 has a gain of one, the case of having 512 columns introduces the significant disadvantage of another 1/8 scaling factor for reducing the weighting of each multiplication product (e.g., constraining the ADC digitization accuracy requirement by almost a factor of eight). Meanwhile, the technology described herein as shown in Eq. 2 would have the same ADC requirement as if there are only sixty-four multiplication products in the partial sum as in Eq. 1 (e.g., as long as there is no data overflow).

(2) An overflow detection stage 28 monitors the output of the analog integration stage 24 to prevent analog values from saturating the input range of the ADC stage 26. In this regard, one challenge of conducting the analog partial sum accumulation process (“partial sum accumulation”) is that the integrated OA value in Eq. 2 can potentially exceed the full-scale input range of the subsequent ADC, resulting in data overflow condition. The overflow detection stage 28 is therefore added after the analog integration stage 24 to protect against such an overflow condition.

More particularly, the overflow prevention solution described herein ensures that the ADC input range saturation does not occur by having timely ADC conversion and integrator reset. As will be discussed in greater detail, the detection can be performed at two points for each OA line 22 (e.g., voltage OAₙ before the integrator and integrator output voltage OA_{int,n}). Accordingly, embodiments can impose a sufficient condition for overflow prevention.

For example, accumulation interruption with integrator reset and ADC conversion can be conducted if either the Aᵢₙₜ·OAₙ value (e.g., OAₙ value with a predetermined integrator gain) or the OA_{int,n} value exceeds half of the ADC input full-scale range. In such a case, analog accumulation would only continue if both the Aᵢₙₜ·OAₙ value and the OA_{int,n} value are within half of the ADC input full-scale range. Specifically, if it is assumed that the ADC input full-scale range is V_{FS_ADC}, the overflow detection threshold, V_{det}, can be set at half of this range (e.g., V_{det}=0.5V_{FS_ADC}), and once Aᵢₙₜ·OAₙ or OA_{int,n} is greater than 0.5V_{FS_ADC}, analog accumulation would stop and ADC conversion would follow. Since the detection threshold for both voltages are half of ADC full scale, it is guaranteed that if both voltages are within this range, the accumulation value after next integration cycle, which is the summation of these two voltages, would not exceed the ADC full scale range. Moreover, the two detection thresholds for Aᵢₙₜ·OAₙ and OA_{int,n} may be different, as long as the summation of the two thresholds is no more than the ADC full scale range (e.g., the detection threshold for Aᵢₙₜ·OAₙ being set as 0.3V_{FS_ADC} and the detection threshold for OA_{int,n} being set as 0.7V_{FS_ADC}).

(3) One or more controllers 30 handle analog accumulation interruption and generate various clocks accordingly. For example, the controller(s) 30 can be connected to the output of the overflow detection stage 28 to handle analog accumulation interruption based on the overflow detector results. When an overflow risk is detected (e.g., OA_{int,n}>0.5V_{FS_ADC} or OAₙ>0.5V_{FS_ADC}/Aᵢₙₜ), an overflow detection signal S_{ovfl} is triggered, and integrator reset and ADC conversion follows. If an overflow risk is not detected but accumulation has gone through all eligible partial sums in one summation or accumulation has used all memory sub-banks in the group 12 (eight in this example), integrator reset and ADC conversion follows as well.

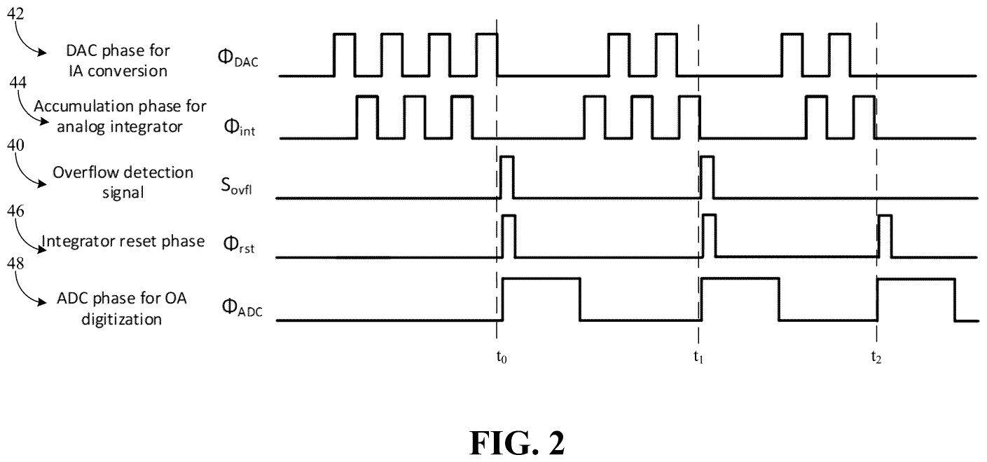

FIG. 2 shows three types of accumulation interruption scenarios. During normal operation, the analog CiM array is going through multiple IA input DAC conversion phases 42 (Φ_{DAC}) followed by an analog integration phases 44 (Φᵢₙₜ) for analog partial sum accumulation. After three cycles of the analog partial sum accumulation process (“partial sum accumulations”) and at the end of the fourth DAC conversion phase (e.g., time to), the OA line value OAₙ exceeds the detection threshold (e.g., 0.5V_{FS_ADC}/Aᵢₙₜ). As a result, analog accumulation interruption occurs in response to the overflow detection signal 40 (S_{ovfl}) being triggered. The overflow detection signal 40 is followed by an integrator reset phase 46 (Φᵣₛₜ) and an ADC conversion phase 48 (Φ_{ADC}), after which the fourth analog integration phase can occur.

After three more cycles of analog integration phases (e.g., time t₁), the integrator output value OA_{int,n} exceeds the detection threshold (e.g., 0.5V_{FS_ADC}). This overflow condition also triggers a pulse of the overflow detection signal 40, followed by integrator reset and ADC conversion.

After two more cycles of analog integration phases (e.g., time t₂), all eight sub-banks of weight storage have encountered partial sum accumulation. Even though there is no overflow risk detected, integrator reset and ADC conversion still follows, since there is no more eligible partial sum for the same summation that can further take place in the MAC array without updating the stored weight data.

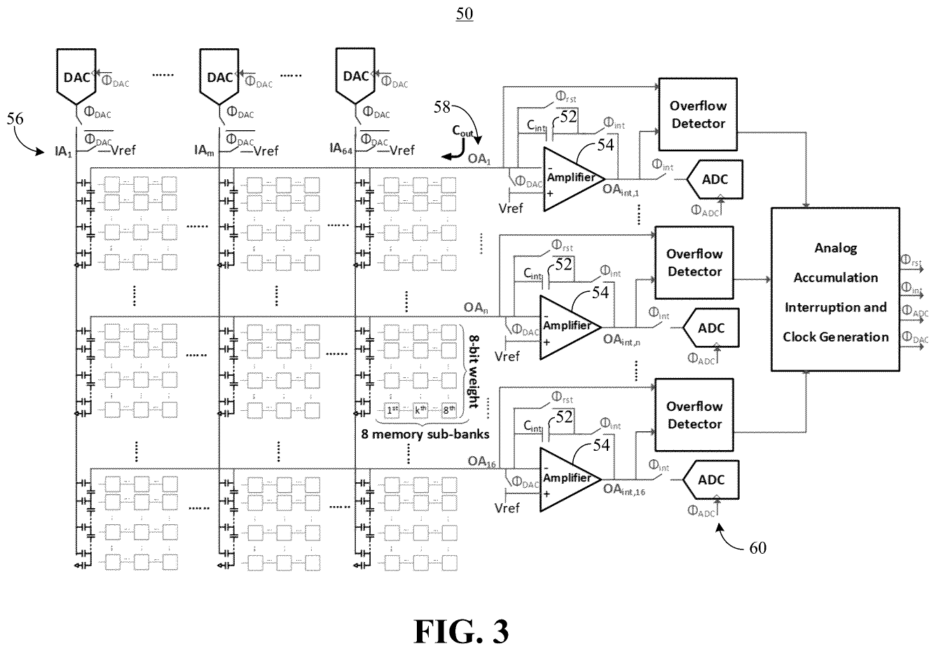

Turning now to FIG. 3, a charge-domain analog CiM circuit 50 is shown. Since for charge-domain analog MAC computation, the analog partial sum value is already stored in capacitors, the analog integration stage 24 (FIG. 1) can be simply implemented as a switched-capacitor integrator with a plurality of integrator capacitors 52 (Cᵢₙₜ) connected across a corresponding plurality of amplifiers 54 for charge accumulation in multiple integration cycles. Various operation phases and circuit functions in this implementation are explained as follows:

(1) During the DAC phase Φ_{DAC}, the values from sixty-four IA lines 56 charge the capacitors in the MAC array, while the OA lines 58 are set to a reference voltage Vref. Immediately after the DAC phase, the OA lines 58 are disconnected from Vref and become floating, while all the IA lines 56 are then connected to Vref, thus pushing the OA voltage to reveal the OA line 58 value OAₙ from the MAC operation. One of the overflow risk detections is then performed at this moment on the OAₙ value.

(2) During the integration phase Φᵢₙₜ, all IA lines 56 are still connected to Vref. At this moment, the switched-capacitor integrator circuit becomes active with the amplifiers 54 configured in closed-loop operation and the OA lines 58 connected to the integration capacitors 52 (Cᵢₙₜ). With the loop feedback mechanism, the OA lines 58 are pinned to Vref, causing all the charges from the capacitors in MAC array to be transferred to the integration capacitors 52, realizing the charge accumulation operation. At the end of the Dint phase, the ADC stage 60 finishes sampling operation and the second overflow detection is performed on OA_{int,n}.

(3) During the integrator reset phase Φᵣₛₜ, the charge on the integration capacitors 52 is cleared.

(4) During the ADC conversion phase Φ_{ADC}, the previously sampled voltage from the integration phase will go through digitization to produce digital output bits.

Benefits of the technology described herein therefore include a significant energy efficiency boost by amortizing ADC energy consumption with an increased number of MAC operations per ADC conversion. The technology described herein also boosts MAC throughput via reduced ADC conversion operation. Additionally, embodiments reduce ADC quantization noise contribution with a reduced number of ADC operations.

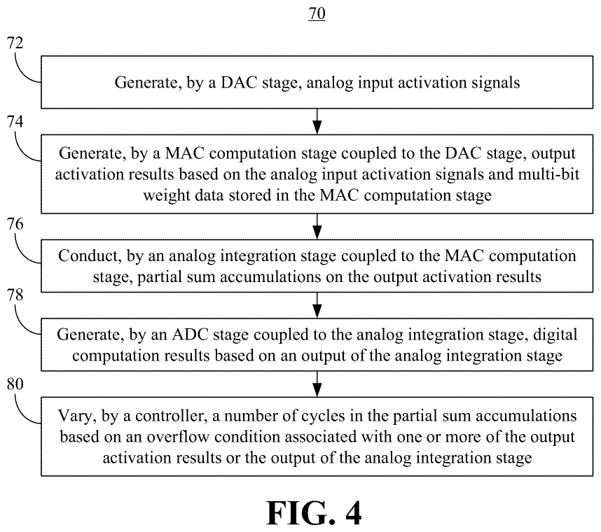

FIG. 4 shows a method 70 of operating an analog CiM circuit. The method 70 may generally be implemented in analog CiM circuit/macro such as, for example, the enhanced analog CiM circuit 10 (FIG. 1) and/or the charge-domain analog CiM circuit 50 (FIG. 3), already discussed. More particularly, the method 70 may be implemented in one or more modules as a set of logic instructions stored in a machine- or computer-readable storage medium such as random access memory (RAM), read only memory (ROM), programmable ROM (PROM), firmware, flash memory, etc., in hardware, or any combination thereof. For example, hardware implementations may include configurable logic, fixed-functionality logic, or any combination thereof. Examples of configurable logic (e.g., configurable hardware) include suitably configured programmable logic arrays (PLAs), field programmable gate arrays (FPGAs), complex programmable logic devices (CPLDs), and general purpose microprocessors. Examples of fixed-functionality logic (e.g., fixed-functionality hardware) include suitably configured application specific integrated circuits (ASICs), combinational logic circuits, and sequential logic circuits. The configurable or fixed-functionality logic can be implemented with complementary metal oxide semiconductor (CMOS) logic circuits, transistor-transistor logic (TTL) logic circuits, or other circuits.

Illustrated processing block 72 provides for generating, by a DAC stage, analog input activation (IA) signals and block 74 generates, by a MAC computation stage coupled to the DAC stage, output activation results based on the analog IA signals and multi-bit weight data stored in the MAC computation stage. In one example, the MAC computation stage includes multiple groups of memory sub-banks to store the multi-bit weight data, wherein each group of memory sub-banks shares an analog computation unit in the MAC computation stage. Block 76 conducts, by an analog integration stage coupled to the MAC computation stage, partial sum accumulations on the output activation results. In an embodiment, the analog integration stage includes a plurality of amplifiers and a plurality of switched integration capacitors corresponding to the plurality of amplifiers. In such a case, the plurality of switched integration capacitors may store the output activation results as a charge accumulation.

Block 78 generates, by an ADC stage coupled to the analog integration stage, digital computation results based on an output of the analog integration stage, wherein block 80 varies, by a controller, a number of cycles in the partial sum accumulations based on an overflow condition associated with one or more of the output activation results or the output of the analog integration stage. In one example, the controller further varies an activation time of the ADC stage based on the overflow condition.

In an embodiment, block 80 also includes generating, by an overflow condition detection stage coupled to the MAC computation stage, the analog integration stage and the controller, one or more signals associated with the overflow condition. For example, the one or more signals may be generated in response to one or more of the output activation results exceeding a first threshold or the output of the analog integration stage exceeding a second threshold. In such a case, a sum of the first threshold and the second threshold can be less than a full-scale range of the ADC stage. The method 70 therefore enhances performance at least to the extent that varying the number of cycles in the partial sum accumulations boosts energy efficiency by amortizing ADC energy consumption with an increased number of MAC operations per ADC conversion, boosts MAC throughput via reduced ADC conversion operation and/or reduces ADC quantization noise contribution with a reduced number of ADC operations.

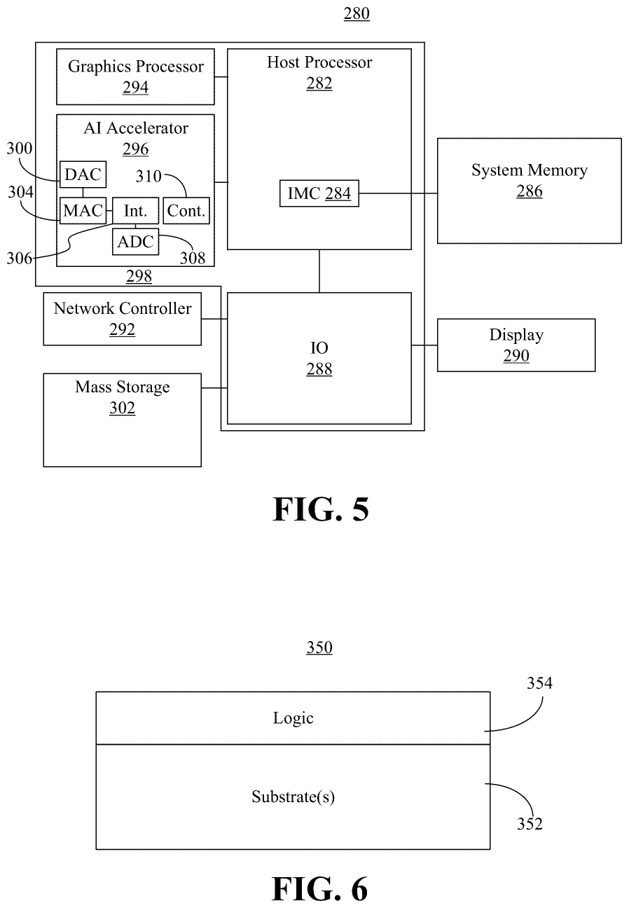

Turning now to FIG. 5, a performance-enhanced computing system 280 is shown. The system 280 may generally be part of an electronic device/platform having computing functionality (e.g., personal digital assistant/PDA, notebook computer, tablet computer, convertible tablet, server), communications functionality (e.g., smart phone), imaging functionality (e.g., camera, camcorder), media playing functionality (e.g., smart television/TV), wearable functionality (e.g., watch, eyewear, headwear, footwear, jewelry), vehicular functionality (e.g., car, truck, motorcycle), robotic functionality (e.g., autonomous robot), Internet of Things (IoT) functionality, drone functionality, etc., or any combination thereof.

In the illustrated example, the system 280 includes a host processor 282 (e.g., central processing unit/CPU) having an integrated memory controller (IMC) 284 that is coupled to a system memory 286 (e.g., dual inline memory module/DIMM). In an embodiment, an IO (input/output) module 288 is coupled to the host processor 282. The illustrated IO module 288 communicates with, for example, a display 290 (e.g., touch screen, liquid crystal display/LCD, light emitting diode/LED display), mass storage 302 (e.g., hard disk drive/HDD, optical disc, solid state drive/SSD) and a network controller 292 (e.g., wired and/or wireless). The host processor 282 may be combined with the IO module 288, a graphics processor 294, and an AI accelerator 296 (e.g., CiM accelerator, specialized processor) into a system on chip (SoC) 298.

In an embodiment, the AI accelerator 296 performs one or more aspects of the method 70 (FIG. 4), already discussed. The AI accelerator 296 may also include the enhanced analog CiM circuit 10 (FIG. 1) and/or the charge-domain analog CiM circuit 50 (FIG. 3), already discussed. Thus, AI accelerator 296 includes a DAC stage 300 to generate analog IA signals and a MAC computation stage 304 coupled to the DAC stage, wherein the MAC computation stage 304 generates OA results based on the analog IA signals and multi-bit weight data stored in the MAC computation stage 304. The AI accelerator 296 also includes an analog integration stage 306 coupled to the MAC computation stage 304, wherein the analog integration stage 306 conducts partial sum accumulations on the output activation results.

An ADC stage 308 is coupled to the analog integration stage 306, wherein ADC stage 308 generates digital computation results based on an output of the analog integration stage 306. The illustrated AI accelerator 296 also includes a controller 310 to vary a number of cycles in the partial sum accumulations based on an overflow condition associated with the OA results and/or the output of the analog integration stage 306. The computing system 280 is therefore considered performance-enhanced at least to the extent that varying the number of cycles in the partial sum accumulations boosts energy efficiency by amortizing ADC energy consumption with an increased number of MAC operations per ADC conversion, boosts MAC throughput via reduced ADC conversion operation and/or reduces ADC quantization noise contribution with a reduced number of ADC operations.

FIG. 6 shows a semiconductor apparatus 350 (e.g., chip, die, package). The illustrated apparatus 350 includes one or more substrates 352 (e.g., silicon, sapphire, gallium arsenide) and logic 354 (e.g., transistor array and other integrated circuit/IC components) coupled to the substrate(s) 352. In an embodiment, the logic 354 implements one or more aspects of the method 70 (FIG. 4), already discussed. Additionally, the logic 354 may include the enhanced analog CiM circuit 10 (FIG. 1) and/or the charge-domain analog CiM circuit 50 (FIG. 3), already discussed. The logic 354 may also include the AI accelerator 296 (FIG. 5), already discussed.

The logic 354 may be implemented at least partly in configurable or fixed-functionality hardware. In one example, the logic 354 includes transistor channel regions that are positioned (e.g., embedded) within the substrate(s) 352. Thus, the interface between the logic 354 and the substrate(s) 352 may not be an abrupt junction. The logic 354 may also be considered to include an epitaxial layer that is grown on an initial wafer of the substrate(s) 352.

### Additional Notes and Examples

Example 1 includes a performance-enhanced computing system comprising a network controller and a processor coupled to the network controller, the processor including a digital to analog conversion (DAC) stage to generate analog input activation signals, a multiply-accumulate (MAC) computation stage coupled to the DAC stage, the MAC computation stage to generate output activation results based on the analog input activation signals and multi-bit weight data stored in the MAC computation stage, an analog integration stage coupled to the MAC computation stage, the analog integration stage to conduct partial sum accumulations on the output activation results, and analog to digital conversion (ADC) stage coupled to the analog integration stage, the ADC stage to generate digital computation results based on an output of the analog integration stage, and a controller to vary a number of cycles in the partial sum accumulations based on an overflow condition associated with one or more of the output activation results or the output of the analog integration stage.

Example 2 includes the computing system of Example 1, wherein the processor further includes an overflow detection stage coupled to the MAC computation stage, the analog integration stage and the controller, the overflow detection stage to generate one or more signals associated with the overflow condition.

Example 3 includes the computing system of Example 2, wherein the overflow detection stage is to generate the one or more signals in response to one or more of the output activation results exceeding a first threshold or the output of the analog integration stage exceeding a second threshold.

Example 4 includes the computing system of Example 3, wherein a sum of the first threshold and the second threshold is less than a full-scale range of the ADC stage.

Example 5 includes the computing system of Example 1, wherein the MAC computation stage includes groups of memory sub-banks to store the multi-bit weight data, and where each group of memory sub-banks shares an analog computation unit in the MAC computation stage.

Example 6 includes the computing system of any one of Examples 1 to 5, wherein the analog integration stage includes a plurality of amplifiers.

Example 7 includes the computing system of Example 6, wherein the analog integration stage further includes a plurality of switched integration capacitors corresponding to the plurality of amplifiers, and wherein the plurality of switched integration capacitors are to store the output activation results as a charge accumulation.

Example 8 includes the computing system of any one of Examples 1 to 7, wherein the controller is further to vary an activation time of the ADC stage based on the overflow condition.

Example 9 includes a semiconductor apparatus comprising a digital to analog conversion (DAC) stage to generate analog input activation signals, a multiply-accumulate (MAC) computation stage coupled to the DAC stage, the MAC computation stage to generate output activation results based on the analog input activation signals and multi-bit weight data stored in the MAC computation stage, an analog integration stage coupled to the MAC computation stage, the analog integration stage to conduct partial sum accumulations on the output activation results, an analog to digital conversion (ADC) stage coupled to the analog integration stage, the ADC stage to generate digital computation results based on an output of the analog integration stage, and a controller to vary a number of cycles in the partial sum accumulations based on an overflow condition associated with one or more of the output activation results or the output of the analog integration stage.

Example 10 includes the semiconductor apparatus of Example 9, further including an overflow detection stage coupled to the MAC computation stage, the analog integration stage and the controller, the overflow detection stage to generate one or more signals associated with the overflow condition.

Example 11 includes the semiconductor apparatus of Example 10, wherein the overflow detection stage is to generate the one or more signals in response to one or more of the output activation results exceeding a first threshold or the output of the analog integration stage exceeding a second threshold.

Example 12 includes the semiconductor apparatus of Example 11, wherein a sum of the first threshold and the second threshold is less than a full-scale range of the ADC stage.

Example 13 includes the semiconductor apparatus of Example 9, wherein the MAC computation stage includes groups of memory sub-banks to store the multi-bit weight data, and where each group of memory sub-banks shares an analog computation unit in the MAC computation stage.

Example 14 includes the semiconductor apparatus of any one of Examples 9 to 13, wherein the analog integration stage includes a plurality of amplifiers.

Example 15 includes the semiconductor apparatus of Example 14, wherein the analog integration stage further includes a plurality of switched integration capacitors corresponding to the plurality of amplifiers, and wherein the plurality of switched integration capacitors are to store the output activation results as a charge accumulation.

Example 16 includes the semiconductor apparatus of any one of Examples 9 to 15, wherein the controller is further to vary an activation time of the ADC stage based on the overflow condition.

Example 17 includes a method comprising generating, by a digital to analog conversion (DAC) stage, analog input activation signals, generating, by a multiply-accumulate (MAC) computation stage coupled to the DAC stage, output activation results based on the analog input activation signals and multi-bit weight data stored in the MAC computation stage, conducting, by an analog integration stage coupled to the MAC computation stage, partial sum accumulations on the output activation results, generating, by an analog to digital conversion (ADC) stage coupled to the analog integration stage, digital computation results based on an output of the analog integration stage, and varying, by a controller, a number of cycles in the partial sum accumulations based on an overflow condition associated with one or more of the output activation results or the output of the analog integration stage.

Example 18 includes the method of Example 17, further including generating, by an overflow detection stage coupled to the MAC computation stage, the analog integration stage and the controller, one or more signals associated with the overflow condition.

Example 19 includes the method of Example 18, wherein the one or more signals are generated in response to one or more of the output activation results exceeding a first threshold or the output of the analog integration stage exceeding a second threshold.

Example 20 includes the method of Example 19, wherein a sum of the first threshold and the second threshold is less than a full-scale range of the ADC stage.

Example 21 includes an apparatus comprising means for performing the method of any one of Examples 17 to 20.

Embodiments are applicable for use with all types of semiconductor integrated circuit (“IC”) chips. Examples of these IC chips include but are not limited to processors, controllers, chipset components, programmable logic arrays (PLAs), memory chips, network chips, systems on chip (SoCs), SSD/NAND controller ASICs, and the like. In addition, in some of the drawings, signal conductor lines are represented with lines. Some may be different, to indicate more constituent signal paths, have a number label, to indicate a number of constituent signal paths, and/or have arrows at one or more ends, to indicate primary information flow direction. This, however, should not be construed in a limiting manner. Rather, such added detail may be used in connection with one or more exemplary embodiments to facilitate easier understanding of a circuit. Any represented signal lines, whether or not having additional information, may actually comprise one or more signals that may travel in multiple directions and may be implemented with any suitable type of signal scheme, e.g., digital or analog lines implemented with differential pairs, optical fiber lines, and/or single-ended lines.

Example sizes/models/values/ranges may have been given, although embodiments are not limited to the same. As manufacturing techniques (e.g., photolithography) mature over time, it is expected that devices of smaller size could be manufactured. In addition, well known power/ground connections to IC chips and other components may or may not be shown within the figures, for simplicity of illustration and discussion, and so as not to obscure certain aspects of the embodiments. Further, arrangements may be shown in block diagram form in order to avoid obscuring embodiments, and also in view of the fact that specifics with respect to implementation of such block diagram arrangements are highly dependent upon the computing system within which the embodiment is to be implemented, i.e., such specifics should be well within purview of one skilled in the art. Where specific details (e.g., circuits) are set forth in order to describe example embodiments, it should be apparent to one skilled in the art that embodiments can be practiced without, or with variation of, these specific details. The description is thus to be regarded as illustrative instead of limiting.

The term “coupled” may be used herein to refer to any type of relationship, direct or indirect, between the components in question, and may apply to electrical, mechanical, fluid, optical, electromagnetic, electromechanical or other connections. In addition, the terms “first”, “second”, etc. may be used herein only to facilitate discussion, and carry no particular temporal or chronological significance unless otherwise indicated.

As used in this application and in the claims, a list of items joined by the term “one or more of” may mean any combination of the listed terms. For example, the phrases “one or more of A, B or C” may mean A; B; C; A and B; A and C; B and C; or A, B and C.

Those skilled in the art will appreciate from the foregoing description that the broad techniques of the embodiments can be implemented in a variety of forms. Therefore, while the embodiments have been described in connection with particular examples thereof, the true scope of the embodiments should not be so limited since other modifications will become apparent to the skilled practitioner upon a study of the drawings, specification, and following claims.

We claim:

1. A computing system comprising:
a network controller; and
a processor coupled to the network controller, the processor including:
a digital to analog conversion (DAC) stage to generate analog input activation signals,
a multiply-accumulate (MAC) computation stage coupled to the DAC stage, the MAC computation stage to generate output activation results based on the analog input activation signals and multi-bit weight data stored in the MAC computation stage,
an analog integration stage coupled to the MAC computation stage, the analog integration stage to conduct partial sum accumulations on the output activation results,
an analog to digital conversion (ADC) stage coupled to the analog integration stage, the ADC stage to generate digital computation results based on an output of the analog integration stage, and
a controller to vary a number of cycles in the partial sum accumulations based on an overflow condition associated with one or more of the output activation results or the output of the analog integration stage.

2. The computing system of claim 1, wherein the processor further includes an overflow detection stage coupled to the MAC computation stage, the analog integration stage and the controller, the overflow detection stage to generate one or more signals associated with the overflow condition.

3. The computing system of claim 2, wherein the overflow detection stage is to generate the one or more signals in response to one or more of the output activation results exceeding a first threshold or the output of the analog integration stage exceeding a second threshold.

4. The computing system of claim 3, wherein a sum of the first threshold and the second threshold is less than a full-scale range of the ADC stage.

5. The computing system of claim 1, wherein the MAC computation stage includes groups of memory sub-banks to store the multi-bit weight data, and where each group of memory sub-banks shares an analog computation unit in the MAC computation stage.

6. The computing system of claim 1, wherein the analog integration stage includes a plurality of amplifiers.

7. The computing system of claim 6, wherein the analog integration stage further includes a plurality of switched integration capacitors corresponding to the plurality of amplifiers, and wherein the plurality of switched integration capacitors are to store the output activation results as a charge accumulation.

8. The computing system of claim 1, wherein the controller is further to vary an activation time of the ADC stage based on the overflow condition.

9. A semiconductor apparatus comprising:
a digital to analog conversion (DAC) stage to generate analog input activation signals;
a multiply-accumulate (MAC) computation stage coupled to the DAC stage, the MAC computation stage to generate output activation results based on the analog input activation signals and multi-bit weight data stored in the MAC computation stage;
an analog integration stage coupled to the MAC computation stage, the analog integration stage to conduct partial sum accumulations on the output activation results;
an analog to digital conversion (ADC) stage coupled to the analog integration stage, the ADC stage to generate digital computation results based on an output of the analog integration stage; and
a controller to vary a number of cycles in the partial sum accumulations based on an overflow condition associated with one or more of the output activation results or the output of the analog integration stage.

10. The semiconductor apparatus of claim 9, further including an overflow detection stage coupled to the MAC computation stage, the analog integration stage and the controller, the overflow detection stage to generate one or more signals associated with the overflow condition.

11. The semiconductor apparatus of claim 10, wherein the overflow detection stage is to generate the one or more signals in response to one or more of the output activation results exceeding a first threshold or the output of the analog integration stage exceeding a second threshold.

12. The semiconductor apparatus of claim 11, wherein a sum of the first threshold and the second threshold is less than a full-scale range of the ADC stage.

13. The semiconductor apparatus of claim 9, wherein the MAC computation stage includes groups of memory sub-banks to store the multi-bit weight data, and where each group of memory sub-banks shares an analog computation unit in the MAC computation stage.

14. The semiconductor apparatus of claim 9, wherein the analog integration stage includes a plurality of amplifiers.

15. The semiconductor apparatus of claim 14, wherein the analog integration stage further includes a plurality of switched integration capacitors corresponding to the plurality of amplifiers, and wherein the plurality of switched integration capacitors are to store the output activation results as a charge accumulation.

16. The semiconductor apparatus of claim 9, wherein the controller is further to vary an activation time of the ADC stage based on the overflow condition.

17. A method comprising:
generating, by a digital to analog conversion (DAC) stage, analog input activation signals;
generating, by a multiply-accumulate (MAC) computation stage coupled to the DAC stage, output activation results based on the analog input activation signals and multi-bit weight data stored in the MAC computation stage;
conducting, by an analog integration stage coupled to the MAC computation stage, partial sum accumulations on the output activation results;
generating, by an analog to digital conversion (ADC) stage coupled to the analog integration stage, digital computation results based on an output of the analog integration stage; and
varying, by a controller, a number of cycles in the partial sum accumulations based on an overflow condition associated with one or more of the output activation results or the output of the analog integration stage.

18. The method of claim 17, further including generating, by an overflow detection stage coupled to the MAC computation stage, the analog integration stage and the controller, one or more signals associated with the overflow condition.

19. The method of claim 18, wherein the one or more signals are generated in response to one or more of the output activation results exceeding a first threshold or the output of the analog integration stage exceeding a second threshold.

20. The method of claim 19, wherein a sum of the first threshold and the second threshold is less than a full-scale range of the ADC stage.
